(19) United States
(12) Patent Application Publication
(10) Pub. No.: US 2012/0322334 A1
(43) Pub. Date: Dec. 20, 2012

(54) METHOD OF MANUFACTURING FILM AND METHOD OF MANUFACTURING DISPLAY

(75) Inventors: Kenichi Kurihara, Kanagawa (JP); Takako Sekiyama, Kanagawa (JP); Masanobu Tanaka, Kanagawa (JP)

(73) Assignee: Sony Corporation, Tokyo (JP)

(21) Appl. No.: 13/487,731

(22) Filed: Jun. 4, 2012

(30) Foreign Application Priority Data
Jun. 15, 2011 (JP) 2011-132948

(51) Int. Cl. H01J 9/20; B41M 1/10

(52) U.S. Cl. 445/24; 101/170

(57) ABSTRACT

There are provided a method of manufacturing a film, suitable for forming a film having a plurality of minute through holes, and a method of manufacturing a display using the method of manufacturing a film. The method of manufacturing a film, includes: transferring a film of a first pattern onto a base material with use of an intaglio plate including the first pattern and a second pattern; and forming a film including through holes on the base material by transferring a film of the second pattern of the intaglio plate onto the film of the first pattern.

### BACKGROUND

The present technology relates to a method of manufacturing a film, suitable for forming an insulating film having a plurality of through holes, and a method of manufacturing a display using the method of manufacturing a film.

Multilayer wiring structures are often used on active matrix substrates provided with a transistor device in order to increase integration degree. In multilayer wiring structures, insulating films (interlayer insulating films) provided with a plurality of through holes (via holes) are used in order to electrically connect upper wiring and lower wiring. In recent years, as the configuration material of such insulating films, organic materials with low-dielectric constant (approximately 2.2 to 4.0) are widely used instead of silicon oxide films.

Through holes of an insulating film are typically formed by a method using a photolithographic technique. Specifically, such a method includes a method in which a photoresist is applied to an insulating film, and then exposure, development, and etching are performed to form a pattern, and a method in which, with use of a photosensitive material as the material of an insulating film, exposure and development are performed to form a pattern. However, such methods using the photolithographic technique entail a large number of processes, which is disadvantageous in terms of cost.

In view of this, methods have been proposed in which through holes of a given pattern are formed on an insulating film with use of a printing technique including, in particular, a screen printing method which is excellent in terms of cost (see, for example, Japanese Unexamined Patent Application Publication Nos. 2000-147781, 2002-273999, 2007-95783, and 2008-147614).

Screen printing is a method in which printing is performed by rubbing a screen mesh on which ink is provided with use of a squeegee to transfer the ink onto a substrate to be printed. Emulsion is previously applied to a region (non-printed region) of the screen mesh corresponding to a portion to which printing is not to be performed. The screen printing is drawing attention since this method has advantages that the number of process may be reduced and material use efficiency is high. In addition, since the screen printing makes it possible to form a fine pattern in a simple way, this method is used in wiring process of touch panels, solar batteries, and the like, in recent years.

### SUMMARY

However, there is an issue that, since in the screen printing, printing is performed through the mesh provided with emulsion in a non-printed region as described above, the screen printing is unsuitable for printing in which a non-printed region is a micro pattern. In particular, when through holes having a given pattern are formed in an insulating film, a non-printed region (pattern of through holes) becomes a dotted pattern, and it is difficult in the screen printing to reduce the size of the dot to less than 100 μm in diameter.

In order to cope with such an issue of the size of the non-printed region, in Japanese Unexamined Patent Application Publication Nos. 2007-95783 and 2008-147614, methods are proposed in which the printing process is divided into two processes to perform fine-pattern printing, but even with these methods, it is still difficult to sufficiently perform fine-pattern printing. This is because, in screen printing methods, a certain degree of distance between a screen mesh and a substrate to be printed is required, and in addition, a plurality of parameters such as an angle, pressure, and speed of a squeegee are influential.

It is desirable to provide a method of manufacturing a film, suitable for forming a film having a plurality of minute through holes, and a method of manufacturing a display using the method of manufacturing a film.

According to an embodiment of the present technology, there is provided a method of manufacturing a film including: transferring a film of a first pattern onto a base material with use of an intaglio plate including the first pattern and a second pattern; and forming a film including through holes on the base material by transferring a film of the second pattern of the intaglio plate onto the film of the first pattern.

According to the embodiment of the present technology, there is provided a method of manufacturing a display, including sequentially forming a thin film transistor, an insulating film, and a display device on a substrate, the forming of an insulating film including: transferring a film of a first pattern onto a base material with use of an intaglio plate including the first pattern and a second pattern; and forming a film including through holes on the base material by transferring a film of the second pattern of the intaglio plate onto the film of the first pattern.

In the method of manufacturing a film and the method of manufacturing a display of an embodiment of the present technology, since a film having through holes is formed by a printing method using an intaglio plate, that is, a gravure offset printing, even in a case where the size of the pattern of a non-printed region (through hole) is minute, it is possible to easily form a film having this pattern on the base material. In particular, since a film having through holes is formed by stacking the film of the first pattern and the film of the second pattern, it is possible to make the size of each of the non-printed region of the first pattern and that of the second pattern larger than a desired size of the through hole.

According to the method of manufacturing a film or the method of manufacturing a display of the embodiment of the present technology, since the film having the through holes is formed by the gravure offset printing, it is possible to easily form the film even in the case where the pattern of the through holes is minute.

It is to be understood that both the foregoing general description and the following detailed description are exemplary, and are intended to provide further explanation of the technology as claimed.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the technology.

FIG. 1 is a top view showing a configuration of an intaglio plate used in a method of manufacturing a film according to an embodiment of the present disclosure.

FIG. 2 is a sectional view showing the configuration of the intaglio plate illustrated in FIG. 1.

FIG. 3 is a view showing the method of manufacturing a film using the intaglio plate illustrated in FIG. 1 in the order of processes.

FIG. 4 is a top view showing a configuration of a film manufactured with use of the intaglio plate illustrated in FIG. 1.

FIG. 5 is a top view showing a configuration of an intaglio plate according to Comparative Example.

FIG. 6 is a top view showing a configuration of an intaglio plate according to a modification.

FIG. 7 is a top view showing another configuration of the intaglio plate illustrated in FIG. 6 according to the modification.

FIG. 8 is a view showing a modification of the method of manufacturing a film illustrated in FIG. 3.

FIG. 9 is a view showing a configuration of a display manufactured with use of the method of manufacturing a film of the embodiment of the present disclosure.

FIG. 10 is a view showing an exemplary pixel driving circuit illustrated in FIG. 9.

FIG. 11 is a sectional view showing a configuration of a display region illustrated in FIG. 9.

### DETAILED DESCRIPTION

Hereinafter, an embodiment of the present technology will be described in detail referring to the figures. The description will be made in the following order.

1. Embodiment: An exemplary case where a first pattern has a belt shape and a second pattern has a rectangular shape
2. Modification: An exemplary case where both of a first pattern and a second pattern have a belt shape

### 3. Application Example: Display

### Embodiment

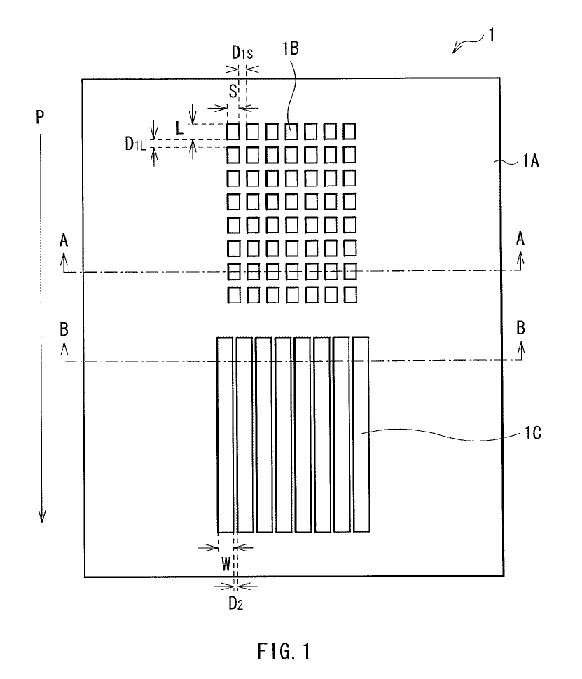

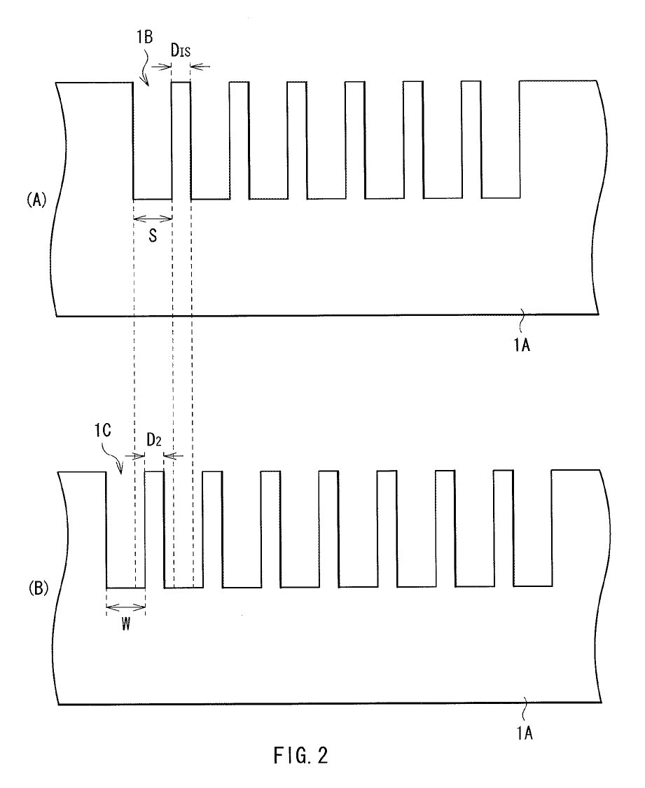

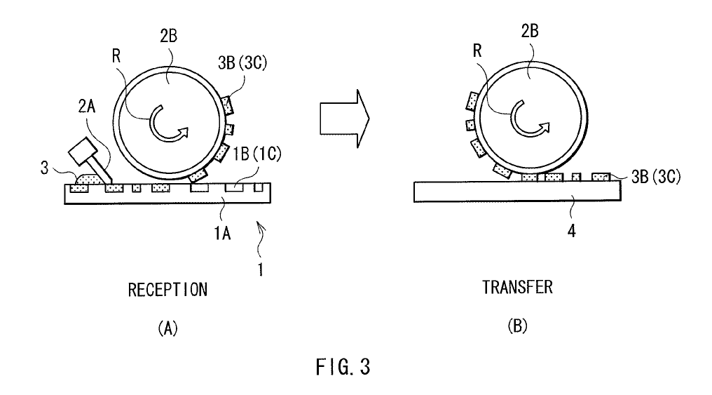

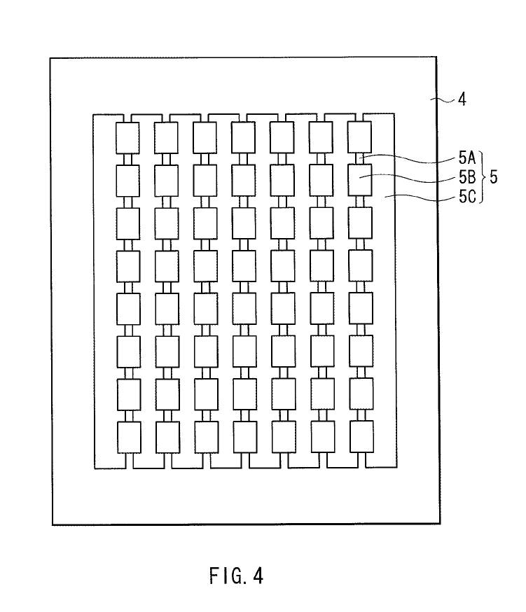

FIG. 1 shows a plan configuration of an intaglio plate (intaglio plate 1) used in a method of manufacturing a film according to an embodiment of the present technology, whereas (A) and (B) of FIG. 2 show cross-sectional configurations taken along A-A line and B-B line of FIG. 1, respectively. In the present embodiment, with use of the intaglio plate 1, gravure offset printing is performed to form an insulating film 5 provided with through holes 5A illustrated in FIG. 4. Although details are described later, in the gravure offset printing, a paste 3 is filled in the intaglio plate 1 with use of a blade 2A, and then the paste 3 is transferred onto a substrate 4 (a substrate or a base material to be printed) through a blanket 2B, as illustrated in FIG. 3.

The material for the intaglio plate 1 includes, for example, glass, quartz, metal, resin, and various ceramics, and the material is not specifically limited as long as it offers sufficient durability against the slide movement of the blade. It is also possible to perform coating with DLC (Diamond-Like Carbon) or the like, or various kinds of surface treatment in order to improve mechanical strength, or to improve printing property.

An intaglio plate main body 1A of the intaglio plate 1 is a flat plate having a rectangular shape, and the blanket 2B is brought into contact with the intaglio plate main body 1A along the long side direction of the intaglio plate main body 1A to perform printing. In other words, the long side direction corresponds to a printing direction P. In this instance, the downward direction in the figure is assumed to be the printing direction P (FIG. 1). In the intaglio plate main body 1A, a pattern in which a plurality of first recessed portions 1B each having a rectangular shape are disposed (first pattern), and a pattern in which a plurality of the second recessed portions 1C each having a belt shape are disposed (second pattern) are provided in this order along the printing direction. The pattern of the first recessed portions 1B and the pattern of the second recessed portions 1C correspond to a pattern of a film (films 3B and 3C of FIG. 3 described later) formed on a blanket (a substrate to be printed), and a part of the film of the pattern of the second recessed portions 1C is overlapped with a part of a region where the film is not formed in accordance with the pattern of the first recessed portions 1B, thereby forming the through holes 5A. The thickness of a film to be formed is determined based on the depth of the first recessed portions 1B and that of the second recessed portions 1C.

The first recessed portion 1B has a rectangular shape with a long side of length L and a short side of length S, and a plurality of the first recessed portions 1B are disposed to form a matrix (steppingstone-like shape), and the long side of the first recessed portion 1B corresponds to the printing direction whereas the short side of the first recessed portion 1B corresponds to a direction perpendicular to the printing direction. It is also possible to dispose the first recessed portions 1B so that the short side thereof corresponds to the printing direction; however, in terms of ease of alignment, printing property, and uniformity of the film thickness, it is preferable to dispose the first recessed portions 1B so that the long side thereof corresponds to the printing direction, and the ratio of the length S to the length L (S/L) is preferably equal to or less than ½. If S/L is larger than ½, the form of a printed film is likely to be lost. The interval of the first recessed portions 1B adjacent to each other is interval D_{1L} in the printing direction, and interval D _{1S} in a direction perpendicular to the printing direction.

The second recessed portion 1C has a belt shape extended in the printing direction with width W, and a plurality of the second recessed portions 1C are disposed in a direction perpendicular to the printing direction. As illustrated in FIG. 2, it is preferable that, as viewed from the printing direction, the second recessed portions 1C be positioned on an extension of raised portions (non-printed regions) of the adjacent first recessed portions 1B. This is because this configuration makes realignment unnecessary when the pattern of the first recessed portions 1B and the pattern of the second recessed portions 1C are printed. The interval of the adjacent second recessed portions 1C is interval D₂.

The size and pitch of each through hole (through hole 5A) are determined based on the interval D_{1L} of the first recessed portions 1B and the interval D₂ of the second recessed portions 1C. For example, in the case where a film having through holes each having a rectangular shape of 20 μm square is to be formed, the interval D_{1L} and the interval D₂ need only be approximately 20 μm. It is to be noted that, the interval D_{1L} and the interval D₂ may be appropriately changed in consideration of volumetric shrinkage or deformation of a formed film, alignment accuracy, and the like.

Preferably, the length S of the first recessed portion 1B is greater than the interval D₂ of the second recessed portions 1C. This is because, in that case, alignment may be easily performed by providing a region where a film formed by the first recessed portions 1B and a film formed by the second recessed portions 1C are overlapped with each other. For example, a combination of the interval D₂ of 20 μm and length S of the interval D₂ of about 140 μm is exemplified, but the values differ depending on the resolution of a display. It is possible to perform, for example, a liquid-repellent treatment such as a surface coating treatment with fluorine on the top faces of raised portions between the adjacent first recessed portions 1B and between the adjacent second recessed portions 1C. With such a liquid-repellent treatment, the paste is unlikely to remain on the top face of the raised portions, and hence scraping of the paste with strong force is unnecessary. Alternatively, it is also possible that fine irregularity is provided on the top face of raised portions to increase specific surface area, instead of the surface coating treatment with fluorine.

FIG. 3 shows a method of manufacturing the insulating film 5 illustrated in FIG. 4 with use of gravure offset printing using the intaglio plate 1 in the order of processes.

In the method of manufacturing the insulating film 5, as illustrated in (A) of FIG. 3, the intaglio plate 1, a stage (not shown) on which the intaglio plate 1 is placed, and a gravure offset printing machine having the blade 2A and the blanket 2B (base material) are used. As the gravure offset printing machine, publicly known gravure offset printing machines may be used. In addition, in the gravure offset printing machine, a blade angle, pressure, stage speed, blanket torso rotation speed, and the like may be freely set, and preferably the operation accuracy of the stage is less than 5 μm.

First, as illustrated in (A) of FIG. 3, the paste 3 is supplied to the first recessed portions 1B, and then the paste 3 in excess is scraped by the blade 2A. At this time, if the top face of the raised portions between the adjacent first recessed portions 1B has been subjected to liquid-repellent treatment, then the paste 3 is unlikely to remain on the top face of the raised portions even in the case where scraping is mildly performed.

The paste 3 contains an organic material of the insulating film 5 in a solvent. Examples of the organic material of the paste 3 include, polyvinyl alcohol, cellulosic polymer, silicon polymer, polyethylene, polystyrene, polyamide, high-molecular-weight polyether, polyvinyl butyral, methacrylic acid ester polymer, acrylic acid ester polymer, and butylmethacrylate resin, which may be used in combination of two or more of them. It is also possible to configure the insulating film 5 by curing the resin contained in the paste 3 by heat or ultra-violet rays. By curing the resin, it is possible to improve the mechanical characteristics, electrical characteristics, chemical characteristics, and the like of the insulating film 5. Examples of the solvent used in the paste 3 include ethylene glycol monobutyl ether, α-terpineol, PGMEA (Propylene Glycol Monomethyl Ether Acetate), and PGME (Propylene Glycol Monomethyl Ether), which may be used in combination of two or more of them.

Particles may be contained in the paste 3 for the purpose of improving the printing property and the electrical characteristics of the insulating film 5. The particles may be either of organic particles or inorganic particles as long as they can exist as particles in the insulating film 5, but inorganic particles are preferable since granularity of inorganic particles is easily controlled, and inorganic particles are easily dispersed in a solvent. Examples of inorganic particles include particles of silica (SiO₂), alumina (Al₂O₃), titanium oxide (TiO₂), zinc oxide (ZnO), and barium titanate (BaTiO₃). Among them, particles having relatively low relative permittivity such as silica, alumina, and zinc oxide are preferable. In addition, porous particles having a mesopore or a micropore in particle structure, such as mesoporous silica, may be adopted.

The mixing ratio of the above-mentioned organic materials and the particles in the paste 3 (the insulating film 5) is not particularly limited. The mixing ratio may be appropriately adjusted to obtain optimum physical properties according to the pattern of the insulating film 5, but in order to ensure the pliability of the insulating film 5, it is preferable to increase the ratio of the organic material. Specifically, the volume ratio of the organic material in the insulating film 5 is preferably 40% or more, and more preferably 50% or more. By increasing the mixing ratio of the organic material as described, the insulating film 5 may be used even in the case where the substrate 4 has flexibility. As the paste 3, a dispersant, a plasticizer, a viscosity modifier, and the like may be added to the above-described mixture of the solvent with the organic material and the particles, as necessary.

After the paste 3 in excess is scraped, the blanket 2B is rotated in the arrow R direction on the intaglio plate 1 as illustrated in (A) of FIG. 3. In this way, the paste 3 filled in the first recessed portions 1B is received by the blanket 2B, and a film 3B having a pattern corresponding to the first recessed portions 1B is formed on the blanket 2B. Similarly, a film 3C having a pattern corresponding to the second recessed portions 1C is formed on the blanket 2B.

Next, as illustrated in (B) of FIG. 3, the blanket 2B is rotated on the substrate 4 in the arrow R direction so as to transfer the film 3B formed on the blanket 2B onto the substrate 4. After the film 3B having the pattern corresponding to the first recessed portions 1B is formed on the substrate 4 in this way, in a similar process, the film 3C having the pattern corresponding to the second recessed portions 1C is formed in a stacked manner on the film 3B having the pattern corresponding to the first recessed portions 1B, and then the resin contained in the paste 3 is cross-linked by heat curing, ultraviolet curing, or the like. The film 3B having the pattern corresponding to the first recessed portions 1B and the film 3C having the pattern corresponding to the second recessed portions 1C are not necessarily entirely overlapped, and it is only necessary that they overlap each other at least in part. In this way, as illustrated in FIG. 4, an insulating film 5B having the pattern corresponding to the first recessed portions 1B and an insulating film 5C having the pattern corresponding to the second recessed portions 1C are formed on the substrate 4, and the insulating film having a plurality of the through holes 5A is completed. It is to be noted that, the paste 3 supplied to the first recessed portions 1B and that supplied to the second recessed portions 1C may be appropriately adjusted according to the area and the form of the pattern of the first recessed portions 1B and the second recessed portions 1C, respectively, but it is preferable that the insulating films 5B and 5C after drying be not greatly different from each other in the composition of the configuration material thereof.

It is also possible to form the film 3B (the insulating film 5B) having the pattern corresponding to the first recessed portions 1B after the film 3C (the insulating film 5C) having the pattern corresponding to the second recessed portions 1C, but preferably the insulating film 5C having a larger film-formation area is formed later. In the latter process, a solvent remaining in the film 3C having the pattern corresponding to the second recessed portions 1C and having the larger area dissolves and levels the organic material and the like contained in the previously formed film 3B having the pattern corresponding to the first recessed portions 1B. Hence, by forming the film 3C having the pattern corresponding to the second recessed portions 1C later, the insulating film 5 having a uniform form (pattern) and a uniform film thickness may be formed. If the film 3B which has the pattern corresponding to the first recessed portions 1B and has smaller area is formed later, since the amount of remaining solvent is small, the leveling may not be sufficiently performed. For the reason described above, the film 3B having the pattern corresponding to the first recessed portions 1B and the film 3C having the pattern corresponding to the second recessed portions 1C are preferably different from each other in the film-formation area thereof, and it is preferable to increase that difference as much as possible.

In addition, since the leveling is performed in the above-described manner, curing of the resin in the paste 3 is preferably performed after the formation of both of the film 3B having the pattern corresponding to the first recessed portions 1B and the film 3C having the pattern corresponding to the second recessed portions 1C. If the curing is performed after the film 3B having the pattern corresponding to the first recessed portions 1B is formed, but before the film 3C having the pattern corresponding to the second recessed portions 1C is formed, the leveling may not be sufficiently performed since the organic insulating film after curing has a high resistance to solvents.

Since, in the present embodiment, the insulating film 5 having the through holes 5A is formed with use of the gravure offset printing using the intaglio plate 1, the through holes 5A may be easily formed even if each of the through holes 5A is minute, and is, for example, 50 μm in diameter.

Methods other than the gravure offset printing, such as a screen printing method may reduce the number of process and the cost, in comparison to the method using the photolithographic technique. However, in the screen printing method, since printing is performed through a mesh provided with emulsion in a non-printed region, the screen printing is unsuitable for printing in which a non-printed region is a micro pattern, and it is difficult to reduce the non-printed region (through hole) to less than 100 μm in diameter. In addition, although a method is also proposed in which screen printing is performed twice to print a fine-pattern, even with this method, it is difficult to form a through hole which has, for example, a square shape of 50 μm square or less or a round shape of 50 μm or less in Φ (diameter), and therefore there is a limitation. This is because, in screen printing methods, a certain degree of distance between a screen mesh and a substrate to be printed is required, and in addition, a plurality of parameters such as the angle, pressure, and speed of a squeegee are influential. Further, in the case where printing is performed twice, the alignment is difficult to perform, and in addition, the film thickness is likely to be uneven.

In contrast, according to the film manufacturing method of the present embodiment, non-printed regions (or regions corresponding to the through holes 5A) are formed by the raised portions between the adjacent first recessed portions 1B and the raised portions between the adjacent second recessed portions 1C of the intaglio plate 1, and the intaglio plate 1 and the blanket 2B are brought into direct contact with each other to form a pattern. In other words, even if the pattern of the through holes 5A is minute, and each of which has a size of, for example, 50 μm square or less, the insulating film 5 having the minute through holes 5A may be formed, with only a little influence of the other components.

In particular, since, in the present embodiment, the insulating film 5 having the through holes 5A is formed by stacking the insulating film 5B having the pattern corresponding to the first recessed portions 1B and the insulating film 5C having the pattern corresponding to the second recessed portions 1C, the size of the respective raised portions between the adjacent first recessed portions 1B and the respective raised portions between the adjacent second recessed portions 1C is greater than a desired size of each through hole 5A.

It is conceivable to perform printing by providing the pattern of the first recessed portions 1B and the pattern of the second recessed portions 1C on separate intaglio plates. However, by sequentially disposing, in a printing direction, the region provided with the pattern corresponding to the first recessed portions 1B and the region provided with the pattern corresponding to the second recessed portions 1C on one intaglio plate main body 1A as in the case of the intaglio plate 1, the insulating film 5 having the through holes 5A may be formed without replacement of the plate. In other words, since alignment associated with the replacement of the plates is not necessary, alignment (superposing) accuracy is improved, and further, since the number of process is decreased, the cost may be reduced.

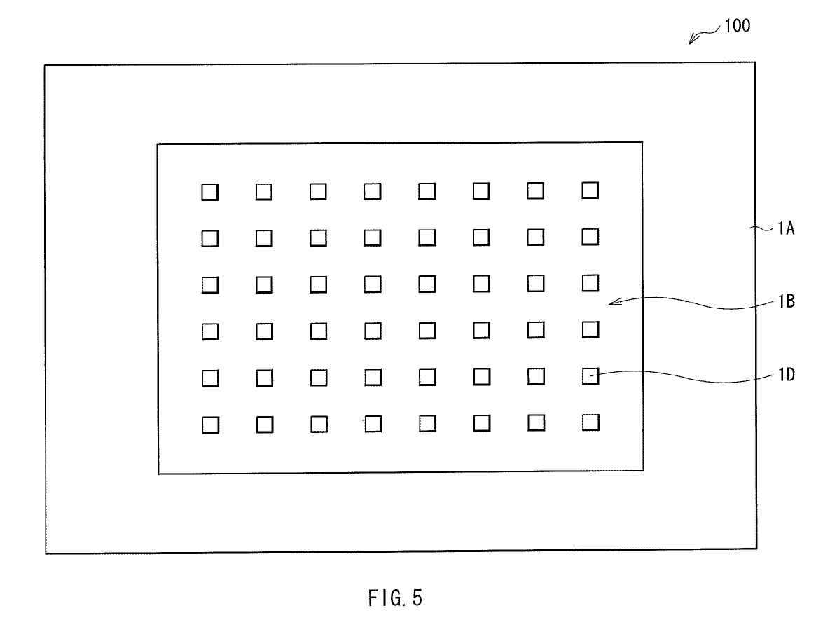

In addition, in the case where the insulating film 5 having the through holes 5A is formed by a single printing process, an intaglio plate (an intaglio plate 100), in which columnar raised portions 1D corresponding to the fine pattern of the through holes 5A are provided in a large recessed portion 1B corresponding to the area of the insulating film 5, is used as illustrated in FIG. 5. Therefore, when the paste 3 in excess is scraped by the blade 2A, the fine raised portions 1D are likely to be damaged, and it is difficult to obtain the insulating film 5 having the accurate pattern of the through holes 5A. In the intaglio plate 1 of the present embodiment, since the size of the respective raised portions between the adjacent first recessed portions 1B and the respective raised portions between the adjacent second recessed portions 1C is greater than the size of each through hole 5A, the possibility of breakage is low, and the insulating film 5 may be stably formed.

As described above, since, in the present embodiment, the insulating film 5 having the through holes 5A is formed by the gravure offset printing with use of the intaglio plate 1, the insulating film 5 may be easily formed even if the pattern of the through holes 5A is minute. In addition, the method of the present embodiment is a simple method which necessitates a fewer number of processes in comparison to methods using the photolithographic technique, and hence the cost may be reduced.

In particular, since the first recessed portions 1B and the second recessed portions 1C having patterns different from each other are provided in one intaglio plate main body 1A, the alignment accuracy is improved and the number of process may be reduced.

### Modifications

While, in the above-mentioned embodiment, a case is described in which the intaglio plate 1 is provided with the first recessed portion 1B having a rectangular shape and the second recessed portion 1C having a belt shape, the form of the first recessed portion 1B and the second recessed portion 1C is not limited to this, and may be appropriately set according to a desired form and size of the through hole 5A.

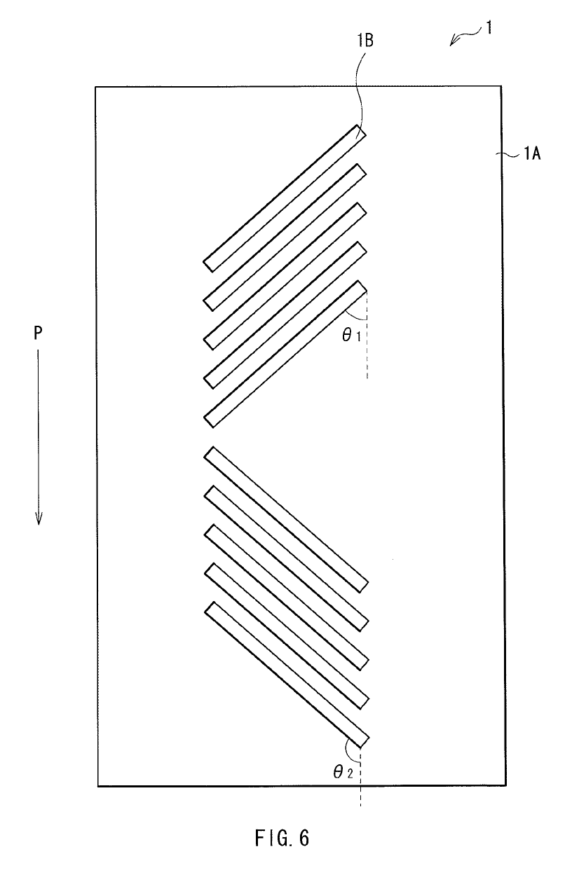

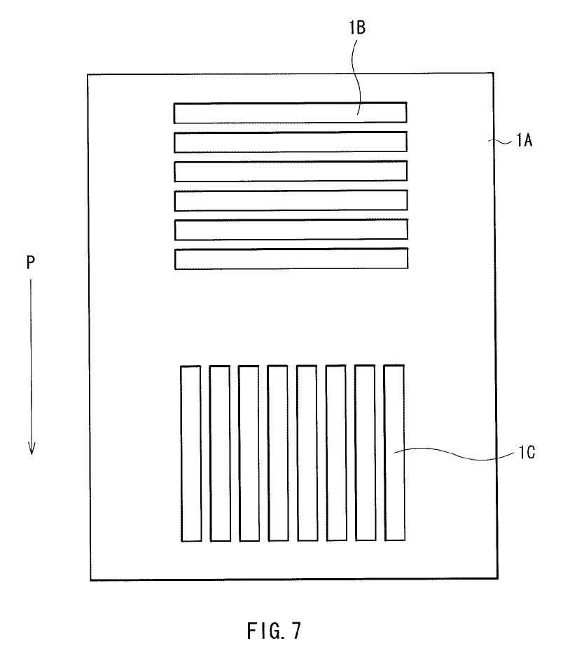

For example, it is also possible that both the first recessed portion 1B and the second recessed portion 1C have a belt shape, and that the first recessed portion 1B and the second recessed portion 1C are inclined by θ1 and θ2 (θ1 ≠θ2), respectively, relative to the printing direction, as illustrated in FIG. 6. In other words, the extending direction of the first recessed portions 1B and the extending direction of the second recessed portions 1C intersect with each other. For example, θ1 is 30 degrees to 60 degrees, and θ2 is 150 degrees to 120 degrees, and more preferably, θ1 is 45 degrees, and θ2 is 135 degrees. In addition, it is also possible to dispose the first recessed portions 1B each having a belt shape in a direction perpendicular to the printing direction, and dispose the second recessed portions 1C each having a belt shape in a direction parallel to the printing direction, as illustrated in FIG. 7.

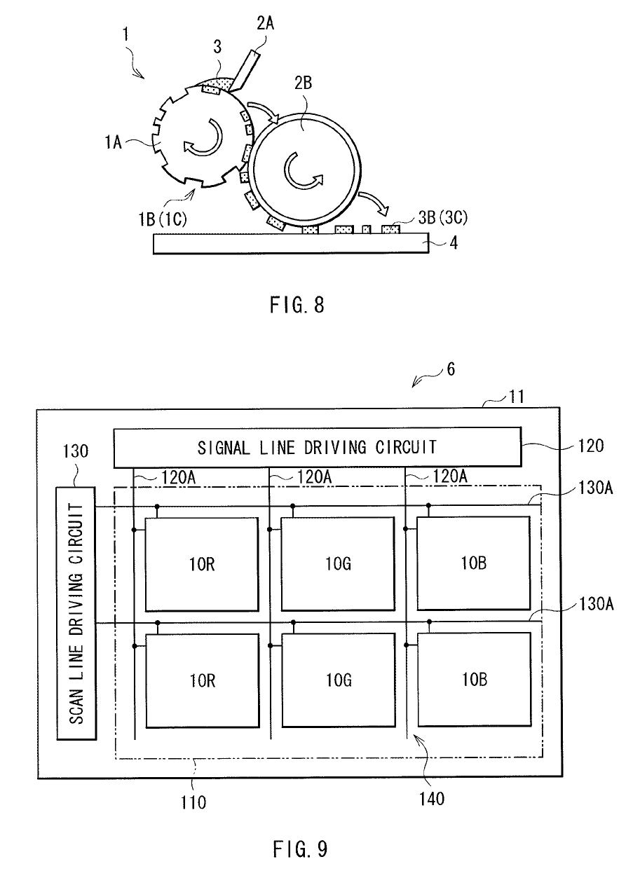

It is to be noted that, while a case where the intaglio plate 1 is a flat plate is described in the above-mentioned embodiment, the intaglio plate 1 may be a cylindrical plate so as to further improve mass productivity, as illustrated in FIG. 8.

### Application Example

The method of manufacturing a film according to the above-mentioned embodiment and modification may be used for manufacturing, for example, a display (display 6) illustrated in FIG. 9 to FIG. 11. The display 6 is an organic EL (Electroluminescence) display in which a plurality of organic EL devices 10R, 10G, and 10B described later are disposed in matrix on a substrate 11 made of glass or the like so as to configure a display region 110 as illustrated in FIG. 9. In a peripheral region of the display region 110, a signal line driving circuit 120 and a scan line driving circuit 130 as drivers for image display are provided.

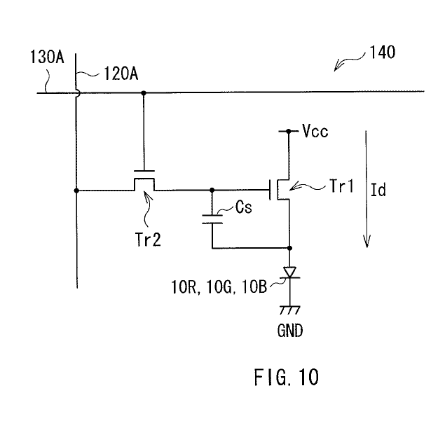

The display region 110 is provided with a pixel driving circuit 140. The pixel driving circuit 140 is an active type driving circuit provided in a lower layer of a first electrode 21 as described later. As illustrated in FIG. 10, the pixel driving circuit 140 has a driving transistor Tr1 and a writing transistor Tr2, and a capacitor Cs is provided in a region between the transistors Tr1 and Tr2. Between a first power-source line (Vcc) and a second power-source line (GND), the organic EL device 10R (or the organic EL device 10G or the organic EL device 10B) is connected to the transistor Tr1 in series. The signal line driving circuit 120 supplies an image signal to a source electrode of the transistor Tr2 through a plurality of signal lines 120A disposed in a column direction. The scan line driving circuit 130 sequentially supplies a scan signal to a gate electrode of the transistor Tr2 through a plurality of scan lines 130A disposed in a row direction. Each of the transistors Tr1 and Tr2 is configured of a commonly used thin film transistor (TFT), and the configuration thereof is not specifically limited. For example, an inversely-staggered structure (so-called bottom-gate type) or a staggered structure (top-gate type) may be adopted.

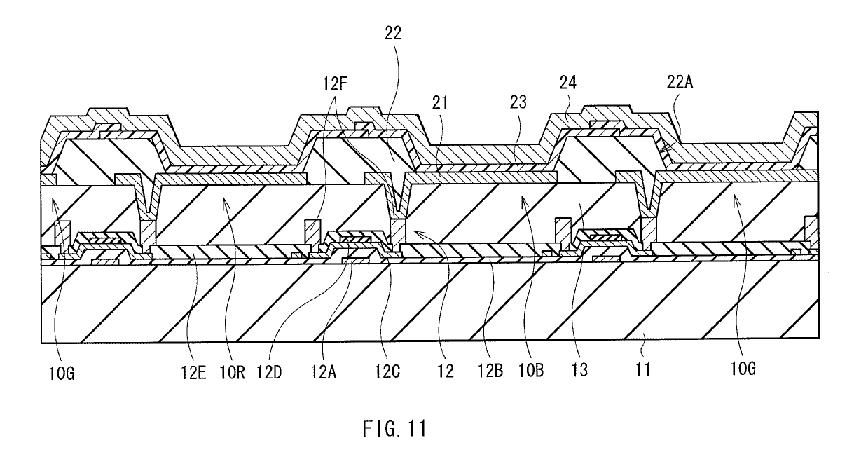

FIG. 11 shows a cross-sectional configuration of the display region 110 illustrated in FIG. 9. On the substrate 11, a TFT 12 as the driving transistor Tr1 of the above-mentioned pixel driving circuit 140, a first insulating film 13, and the organic EL devices 10R, 10G, and 10B are provided in this order from the substrate 11 side. The organic EL devices 10R, 10G, and 10B are, as necessary, covered by a protect film (not shown) made of silicon nitride (SiN) or the like. A sealing substrate made of glass or the like is bonded on the protect film through a bonding layer made of an ultraviolet curable resin, a thermoset resin, or the like.

The TFT 12 configures the driving transistor Tr1 of the pixel driving circuit 140, and is, for example, a bottom-gate (inversely-staggered) type TFT in which a gate electrode 12A made of molybdenum (Mo), a gate insulating film 12B made of silicon nitride (SiNₓ) or the like, a semiconductor film 12C made of amorphous silicon (a-Si), a channel protect film 12D made of silicon nitride or the like, a second insulating film 12E, a source-drain electrode 12F made of aluminum (Al) or the like are laminated in this order on the substrate 11. It is to be noted that, the writing transistor Tr2 illustrated in FIG. 10 also has a configuration similar to that of the TFT 12. The semiconductor film 12C may be configured by an oxide semiconductor or an organic semiconductor (organic material having the property of semiconductors).

In this instance, the first insulating film 13 is formed by the above-mentioned method of manufacturing a film. In other words, the first insulating film 13 corresponds to the insulating film 5 having the through holes 5A. The through hole 5A has a function as a connecting hole which connects the source-drain electrode 12F of the TFT 12 and the first electrode (lower electrode) 21 of the organic EL devices 10R, 10G, and 10B.

In the TFT 12 having a laminated structure, as high integration advances, the more improved superposing accuracy with the first electrode 21 is desired. However, when the first insulating film 13 is formed by the screen printing method, it has been difficult to realize a superposing accuracy of 50 μm or less, let alone 30 μm or less. This is because, in the screen printing method, as described above, a certain degree of distance between a screen mesh and a substrate to be printed is required, and in addition, a plurality of parameters such as the angle, pressure, and speed of a squeegee are influential. In contrast, since the first insulating film 13 is formed by the gravure offset printing in the present embodiment, a film formation may be performed with a high superposing accuracy of about 10 μm, for example.

Each of the organic EL devices 10R, 10G, and 10B is provided on the first insulating film 13, and has a configuration in which the first electrode 21, the third insulating film 22, an organic layer 23 containing a light emitting layer, and a second electrode 24 are laminated in this order from the substrate 11 side.

The first electrode 21 is formed so as to correspond to each of the organic EL devices 10R, 10G, and 10B. The first electrode 21 has, for example, a configuration in which a titanium (Ti) layer having a thickness of about 20 nm and an aluminum alloy layer having a thickness of about 100 nm are laminated in this order from the substrate 11 side, and light generated in the light emitting layer is extracted from the second electrode 24 side (top emission). It is to be noted that, the examples of the configuration material of the first electrode 21 include, in addition to aluminum and its alloys, metallic elements such as chromium (Cr), gold (Au), platinum (Pt), nickel (Ni), copper (Cu), tungsten (W), molybdenum (Mo), silver (Ag), and their alloys. The first electrode 21 extends also to the first insulating film 13, that is, to the inside of the through holes 5A of the insulating film 5, and is connected to the source-drain electrode 12F of the TFT 12.

The third insulating film 22 ensures insulation property between the first electrode 21 and the second electrode 24 and ensures a desired form of light emitting region with accuracy, and is configured by, for example, a photosensitive resin such as silicon oxide, and polyimide having a thickness of 1 μm. The third insulating film 22 is provided with an opening part 22A corresponding to the light emitting region. It is to be noted that, although the organic layer 23 and the second electrode 24 are continuously provided also on the third insulating film 22, light emission occurs only at the opening part 22A of the third insulating film 22.

The organic layer 23 has a configuration in which a hole injection layer, a hole transport layer, the light emitting layer, an electron transport layer, and an electron injection layer are laminated in this order from the first electrode 21 side, for example; however, among these layers, the layers other than the light emitting layer may be arbitrarily provided as necessary. In addition, the configuration of the organic layer 23 may be different depending on the emitting colors of the organic EL devices 10R, 10G, and 10B. The hole injection layer enhances hole injection efficiency, and has a function as a buffer layer for preventing leakage. The hole transport layer enhances hole transport efficiency to the light emitting layer. The light emitting layer generates light when an electric field is applied thereto to cause a recombination of an electron and a hole. The electron transport layer enhances electron transport efficiency to the light emitting layer. The electron injection layer enhances electron injection efficiency, and made of, for example, lithium oxide (Li₂O), lithium fluoride (LiF) or the like having a thickness of about 0.3 nm.

A hole injection layer of the organic EL element 10R has, for example, a thickness of 5 nm or more and 300 nm or less, and is configured by 4,4′,4″-tris (3-methyl phenyl phenylamino) triphenylamine (m-MTDATA) or 4,4′,4″-tris (2-naphthyl phenylamino) triphenylamine (2-TNATA). A hole transport layer of the organic EL device 10R has, for example, a thickness of 5 nm or more and 300 nm or less, and is configured by bis [(N-naphthyl)-N-phenyl] benzidine (α-NPD). A red light emitting layer of the organic EL device 10R has, for example, a thickness of 10 nm or more and 100 nm or less, and is configured by 9,10-di-(2-naphthyl) anthracene (ADN) mixed with 30% of 2,6-bis [4′-methoxy diphenylamino styryl]-1,5-dicyano naphthalene (BSN). An electron transport layer of the organic EL device 10R has, for example, a thickness of 5 nm or more and 300 nm or less, and is configured by 8-hydroxyquinoline aluminum (Alq₃).

A hole injection layer of the organic EL device 10G has, for example, a thickness of 5 nm or more and 300 nm or less, and is configured by m-MTDATA or 2-TNATA. A hole transport layer of the organic EL device 10G has, for example, a thickness of 5 nm or more and 300 nm or less, and is configured by α-NPD. A green light emitting layer of the organic EL device 10G has, for example, a thickness of 10 nm or more and 100 nm or less, and is configured by ADN mixed with 5 volume % of coumalin 6. An electron transport layer of the organic EL device 10G has, for example, a thickness of 5 nm or more and 300 nm or less, and is configured by Algₐ.

A hole injection layer of the organic EL device 10B has, for example, a thickness of 5 nm or more and 300 nm or less, and is configured by m-MTDATA or 2-TNATA. A hole transport layer of the organic EL device 10B has, for example, a thickness of 5 nm or more and 300 nm or less, and is configured by a-NPD. A blue light emitting layer of the organic EL device 10B has, for example, a thickness of 10 nm or more and 100 nm or less, and is configured by ADN mixed with 2.5 weight % of 4,4′-bis [2-{4-(N,N-diphenylamino) phenyl} vinyl] biphenyl (DPAVBi). An electron transport layer of the organic EL device 10B has, for example, a thickness of 5 nm or more and 300 nm or less, and is configured by Algₐ.

The second electrode 24 is provided on the upper surface of the organic layer 23 all over the display region 110, and shared by the organic EL devices 10R, 10G, and 10B. The second electrode 24 has a configuration in which a first layer having a thickness of approximately 0.3 nm and made of lithium fluoride, a second layer having a thickness of 3 nm and made of calcium (Ca), and a third layer having a thickness of 5 nm and made of a Mg—Ag alloy are laminated in this order from the first electrode 21 side, for example. The second electrode 24 is connected to an auxiliary wiring (not shown in the figure) in a region outside of the display region 110. The auxiliary wiring is configured by a conducting film having a frame shape surrounding the display region 110.

For example, the display 6 is manufactured in the following manner.

First, the TFT 12 is formed on the substrate 11 made of glass, and then the pixel driving circuit 140 is formed. Subsequently, by taking the substrate 11 on which the pixel driving circuit 140 is formed as the substrate 4, the insulating film 5 having the through holes 5A is formed with use of the above-mentioned method of manufacturing a film. In this way, the first insulating film 13 is formed.

Next, a titanium film and an aluminum alloy film are formed by, for example, the sputtering method, and then shaped by, for example, the photolithography method and the dry etching to obtain a predetermined form. In this way, in the display region 110, the first electrode 21 in which a titanium layer and an aluminum alloy layer are laminated is formed.

Subsequently, a photosensitive insulation material such as polyimide is applied to the substrate 11 provided with the first electrode 21, and exposure and development are performed by the photolithography. In this way, the third insulating film 22 having the opening part 22A is formed.

After the third insulating film 22 is formed, the organic layer 23 and the second electrode 24 made of the above-mentioned material are formed by a deposition method, for example. In this way, the organic EL devices 10R, 10G, and 10B illustrated in FIG. 10 are formed.

As necessary, a protect film (not shown) made of the above-mentioned material is formed on the organic EL devices 10R, 10G, and 10B by, for example, a CVD (Chemical Vapor Deposition) method or a sputtering method. In addition, a sealing substrate (not shown) in which a color filter or the like is formed is prepared, and the sealing substrate is bonded on the protect film through a bonding layer (not shown). Thus, the display 6 illustrated in FIG. 8 to FIG. 10 is completed.

In the display 6, a scan signal is supplied to each pixel from the scan line driving circuit 130 through the gate electrode of the writing transistor Tr2, and an image signal from the signal line driving circuit 120 is held in the capacitor Cs through the writing transistor Tr2. In other words, the driving transistor Tr1 is on-off controlled according to the signal held in the capacitor Cs, and consequently, a driving current Id is injected into the organic EL devices 10R, 10G, and 10B, whereby a recombination of a hole and an electron is caused to generate light. The light passes through the second electrode 24, the protect film, the bonding layer, the color filter, and the sealing substrate (not shown in the figure except for the second electrode 24) (top emission) and then the light is extracted. In this instance, since the first insulating film 13 is formed by the method of manufacturing a film of the above-mentioned embodiment, it is possible to easily form the first insulating film 13 even if the size of the through hole (the through holes 5A) is minute, and adapt to high integration. Therefore, the thickness and weight of the display 6 may be reduced, and further, in comparison to methods using the photolithographic technique, the display 6 may be manufactured in a simple way at lower cost.

### EXAMPLE

Below, a specific example of the present technology will be described.

### Example 1

Similarly to the above-mentioned embodiment, the insulating film 5 was manufactured. In this instance, the intaglio plate main body 1A made of quartz provided with the first recessed portions 1B each having a rectangular shape and the second recessed portions 1C each having a belt shape was used as the intaglio plate 1. The long side length L of the first recessed portion was 135 μm while the short side length S thereof was 40 μm, and the printing direction was set to correspond to the long side of the first recessed portion 1B while the direction perpendicular to the printing direction was set to correspond to the short side of the first recessed portion 1B. The first recessed portions 1B were disposed in matrix or a steppingstone-like shape (see FIG. 1). The interval D_{1L} of the adjacent first recessed portions 1B in the printing direction was set to 15 μm, and the interval D_{1S} of the adjacent first recessed portions 1B in the direction perpendicular to the printing direction was set to 110 μm.

A plurality of the second recessed portions 1C each of which has a belt shape extending in the printing direction and has the width W of 140 μm were disposed in the direction perpendicular to the printing direction (see FIG. 1). The interval D₂ of the adjacent second recessed portions 1C was set to 10 μm.

As the paste 3, a polyvinyl alcohol resin which is dissolved in a mixed solvent of ethylene glycol monobutyl ether and a-terpineol and to which alumina filler having a specific surface area of 50 m²/g is added to adjust the viscosity to approximately 150 Pa second was used.

After the alignment of the through holes 5A to be formed was performed, with use of the above-mentioned intaglio plate 1 and the above-mentioned paste 3, the film 3B having the pattern corresponding to the first recessed portions 1B was formed on the substrate 4 by gravure offset printing. The film 3B having the pattern corresponding to the first recessed portions 1B thus formed were a plurality of rectangular portions each of which had the long side of 135 μm and the short side of approximately 35 μm in the actual measured value and which were disposed in matrix. Each interval of the rectangular portions in the printing direction was 15 μm, and each interval in the direction perpendicular to the printing direction was 115 μm.

After the film 3B having the pattern corresponding to the first recessed portions 1B was formed, in a similar manner, the film 3C having the pattern corresponding to the second recessed portions 1C was successively formed on this film 3B by gravure offset printing. The film 3C having the pattern corresponding to the second recessed portions 1C thus formed were belt-shaped films each of which had a width of approximately 135 μm and which were disposed in the direction perpendicular to the printing direction at the intervals of 15 μm in the actual measured value.

By stacking the film 3B having the pattern corresponding to the first recessed portions 1B and the film 3C having the pattern corresponding to the second recessed portions 1C, a plurality of the through holes 5A each having a somewhat rounded square shape of 15 μm square were obtained. Finally, the stacked film was dried in an oven heated to 100° C. for 30 minutes, and therefore the insulating film 5 having a plurality of the through holes 5A was completed.

### Example 2

The length L of the long side of the first recessed portion was set to 130 μm, the length S of the short side thereof was set to 40 μm, the interval D_{1L} was set to 20 μm, the interval D_{1S} was set to 110 μm, the width W of the second recessed portion 1C was set to 135 μm, and the interval D₂ was set to 15 μm. Under these conditions and other conditions similar to those of Example 1, the insulating film 5 was manufactured. As a result, the insulating film 5 having a plurality of the through holes 5A each having a somewhat rounded square shape of 20 μm square was obtained.

### Example 3

The length L of the long side of the first recessed portion was set to 145 μm, the length S of the short side thereof was set to 30 μm, the interval D_{1L} was set to 5 μm, the interval D_{1S} was set to 120 μm, the width W of the second recessed portion 1C was set to 145 μm, and the interval D₂ was set to 5 μm. Under these conditions and other conditions similar to those of Example 1, the insulating film 5 was manufactured. As a result, the insulating film 5 having a plurality of the through holes 5A each having a somewhat rounded square shape of 5 μm square was obtained.

### Example 4

Except that the order of forming the film 3B having the pattern corresponding to the first recessed portions 1B and the film 3C having the pattern corresponding to the second recessed portions 1C was changed, the insulating film 5 was created in a manner similar to that of Example 1. Specifically, after the film 3C having the pattern corresponding to the second recessed portions 1C was formed, the film 3B having the pattern corresponding to the first recessed portions 1B was formed. As a result, the insulating film 5 having a plurality of the through holes 5A each having a somewhat rounded square shape of 15 μm square was obtained; however, the form (pattern) and the film thickness were uneven in comparison to Example 1.

### Comparative Example

As the intaglio plate, the intaglio plate 100 (FIG. 5) in which the columnar raised portions 1D corresponding to the pattern of the through holes 5A were provided in the large recessed portion 1B corresponding to the area of the insulating film 5 was used. Under this condition and other conditions similar to those of Example 1, the insulating film 5 was manufactured. The raised portion 1D was formed to have a square shape of 15 μm square. As a result, the raised portion 1D (the intaglio plate 100) was damaged when the paste 3 in excess was scraped by the blade 2A, and the insulating film 5 having the through holes 5A was not formed.

As seen from the above Examples 1 to 4, the through hole 5A of 15 μm square was formed when the interval D_{1L} of the first recessed portions 1B was set to 15 μm and the interval D₂ of the second recessed portions 1C was set to 10 μm. Also, the through hole 5A of 20 μm square was formed when the interval D_{1L} of the first recessed portions 1B was set to 20 μm and the interval D₂ of the second recessed portions 1C was set to 15 μm. Also, the through hole 5A of 5 μm square was formed when the interval D_{1L} of the first recessed portions 1B was set to 5 μm and the interval D₂ of the second recessed portions 1C was set to 5 pm. As described, it was confirmed that the fine through holes 5A each having the size of 50 μm square or less, which are difficult to form in the case of the screen printing method, are easily formed.

In addition, as seen from the comparison of Example 1 with Example 4, it was confirmed that, when the film 3B having the pattern corresponding to the first recessed portions 1B and having a larger film-formation area is formed later, the insulating film 5 having more uniform form and more uniform film thickness may be formed.

Further, as seen from Example 1 and Comparative Example, it was found that, since the fine columnar raised portions 1D of the intaglio plate 100 is easily damaged, when the method in which the film 3B having the pattern corresponding to the first recessed portions 1B and the film 3B having the pattern corresponding to the second recessed portions 1C are stacked is adopted, the insulating film 5 having a plurality of the through holes 5A may be stably formed.

Although the present technology has been described so far based on the embodiment and modifications, the present technology is not limited to the above-mentioned embodiment and so forth, and various modifications may be made. For example, the form of the first recessed portions 1B is not limited to the rectangular shape as long as printing property is ensured. For example, the form of the first recessed portions 1B may be appropriately designed in a circular shape and other polygonal shapes according to the form of the through holes 5A. Additionally, films other than the insulating film may alternatively be formed.

In addition, while, in the above-mentioned embodiment and so forth, the method is described in which the paste 3 filled in the first recessed portions 1B and the second recessed portions 1C is transferred onto the substrate 4 through the blanket 2B, the paste 3 filled in the first recessed portions 1B and the second recessed portions 1C may be directly transferred onto the substrate 4 without using the blanket 2B.

Further, while, in the above-mentioned application example, an exemplary case (top emission) in which the light generated at the light emitting layer is extracted from the second electrode 24 side is described, the light generated at the light emitting layer may be extracted from the substrate 11 side (bottom emission).

On top of that, for example, the material and the thickness of each layer, the film formation methods, the film formation conditions, and the like described in the above-mentioned embodiment and so forth and the application example thereof are not limitative, and other materials, thickness, other film formation methods, and other film formation conditions may be adopted.

Further, while, in the above-mentioned embodiment and so forth, an exemplary case is described in which the method of manufacturing a film of the embodiment of the present disclosure is applied to the method of manufacturing a display including the organic EL device, the method of manufacturing a film of the embodiment of the present disclosure may also be applied to methods of manufacturing a display including various types of display devices such as an inorganic EL device, a liquid crystal device, and an electrophoretic display device.

Note that the present technology may be configured as follows.

(1) A method of manufacturing a film, including:
transferring a film of a first pattern onto a base material with use of an intaglio plate including the first pattern and a second pattern; and
forming a film including through holes on the base material by transferring a film of the second pattern of the intaglio plate onto the film of the first pattern.
(2) The method according to (1), wherein
the first pattern is configured by a plurality of rectangular-recessed portions disposed in matrix, and
the second pattern is configured by a plurality of belt-shaped recessed portions extending in the same direction.
(3) The method according to (1), wherein
the first pattern is configured by a plurality of belt-shaped recessed portions extending in the same direction, and
the second pattern is configured by a plurality of belt-shaped recessed portions extending in the same direction, the extending direction of the recessed portions of the second pattern intersecting with the extending direction of the recessed portions of the first pattern.
(4) The method according to (2) or (3), wherein a paste filled in the recessed portions is transferred onto the base material to form the film of the first pattern and the film of the second pattern.
(5) The method according to any one of (1) to (3), wherein the film of the first pattern and the film of the second pattern are formed by gravure offset printing.
(6) The method according to any one of (1) to (5), wherein the intaglio plate is a flat plate.
(7) The method according to any one of (1) to (5), wherein the intaglio plate is a cylindrical plate.
(8) A method of manufacturing a display, including sequentially forming a thin film transistor, an insulating film, and a display device on a substrate,
the forming of an insulating film including:
transferring a film of a first pattern onto a base material with use of an intaglio plate including the first pattern and a second pattern; and
forming a film including through holes on the base material by transferring a film of the second pattern of the intaglio plate onto the film of the first pattern.

The present disclosure contains subject matter related to that disclosed in Japanese Priority Patent Application JP 2011-132948 filed in the Japan Patent Office on Jun. 15, 2011, the entire content of which is hereby incorporated by reference.

It should be understood by those skilled in the art that various modifications, combinations, sub-combinations, and alterations may occur depending on design requirements and other factors insofar as they are within the scope of the appended claims or the equivalents thereof.

What is claimed is:

1. A method of manufacturing a film, comprising:
transferring a film of a first pattern onto a base material with use of an intaglio plate including the first pattern and a second pattern; and
forming a film including through holes on the base material by transferring a film of the second pattern of the intaglio plate onto the film of the first pattern.

2. The method according to claim 1, wherein
the first pattern is configured by a plurality of rectangular-recessed portions disposed in matrix, and
the second pattern is configured by a plurality of belt-shaped recessed portions extending in the same direction.

3. The method according to claim 1, wherein
the first pattern is configured by a plurality of belt-shaped recessed portions extending in the same direction, and
the second pattern is configured by a plurality of belt-shaped recessed portions extending in the same direction, the extending direction of the recessed portions of the second pattern intersecting with the extending direction of the recessed portions of the first pattern.

4. The method according to claim 2, wherein a paste filled in the recessed portions is transferred onto the base material to form the film of the first pattern and the film of the second pattern.

5. The method according to claim 1, wherein the film of the first pattern and the film of the second pattern are formed by gravure offset printing.

6. The method according to claim 1, wherein the intaglio plate is a flat plate.

7. The method according to claim 1, wherein the intaglio plate is a cylindrical plate.

8. A method of manufacturing a display, including sequentially forming a thin film transistor, an insulating film, and a display device on a substrate,
the forming of an insulating film comprising:
transferring a film of a first pattern onto a base material with use of an intaglio plate including the first pattern and a second pattern; and
forming a film including through holes on the base material by transferring a film of the second pattern of the intaglio plate onto the film of the first pattern.
